(19) United States
(12) Patent Application Publication
(10) Pub. No.: US 2026/0348539 A1
(43) Pub. Date: Nov. 5, 2026

(54) LED BEAD, LED LIGHT STRIP AND CABLE

(71) Applicant: GUANGDONG OPSCO TECHNOLOGY CO., LTD, Dongguan (CN)

(72) Inventors: MINGJIAN LIU, Dongguan (CN); GENGSHENG ZHU, Dongguan (CN); ZHENLEI WU, Dongguan (CN)

(21) Appl. No.: 19/712,373

(22) Filed: Jun. 18, 2026

Related U.S. Application Data
(63) Continuation of application No. PCT/CN2024/134993, filed on Nov. 27, 2024.

(30) Foreign Application Priority Data
May 11, 2024 (CN) 2024105794148

(51) Int. Cl. F21S 4/10; F21V 19/00; F21V 23/00; F21Y 113/17; F21Y 115/10

(52) U.S. Cl. CPC F21S 4/10; F21V 19/0025; F21V 19/005; F21V 23/007; F21Y 2113/17; F21Y 2115/10

(57) ABSTRACT

An LED bead, an LED light strip and a cable include a first insulating base, a first light-emitting assembly, a second light-emitting assembly, a first encapsulant and a second encapsulant. The first light-emitting assembly is disposed on a first end surface; the second light-emitting assembly is disposed on a second end surface; the first encapsulant is disposed on the exterior of the first light-emitting assembly and forms a first boss structure with the first insulating base; the second encapsulant is disposed on the exterior of the second light-emitting assembly and forms a second boss structure with the first insulating base.

### CROSS-REFERENCE TO RELATED APPLICATIONS

This application claims priority to the Chinese Patent Application No. 202410579414.8, filed with the China National Intellectual Property Administration on May 11, 2024 and entitled “LED BEAD, LED LIGHT STRIP AND CABLE”, the entire contents of which are incorporated herein by reference.

### TECHNICAL FIELD

The present disclosure relates to the field of LED technology, and in particular, to an LED bead, an LED light strip and a cable.

### BACKGROUND

With the rapid development of the electronics industry, electronic products have gained widespread popularity in people's daily lives. Data cables for data transmission or charging of electronic products have become an indispensable part of our lives.

Existing data cables emit light via LED light strings disposed on USB connectors and charging plugs at both ends of the cable structure, and light is guided outward by forming notches on the surface of an optical fiber, so that the cable appears luminous to the naked eye. However, as the number of light spots emitted from the cable depends on the number of notches on the surface of the optical fiber, and substantially only a single type of light source is provided for light emission along the whole cable, the light-emitting pattern of the entire cable is monotonous.

### SUMMARY OF THE INVENTION

The present disclosure provides an LED bead, an LED light strip and a cable. Corresponding light-emitting assemblies can be provided on the upper and lower sides of the LED bead, and consistent light-emitting effects on both sides of the bead are achieved. Therefore, the color effect, display effect and resolution of the LED light strip or the cable including a plurality of LED beads are richer and more delicate.

According to a first aspect of the present disclosure, the present disclosure provides an LED bead, including:
a first insulating base, wherein the first insulating base includes a first end surface and a second end surface disposed opposite to each other;
a first pin, wherein the first pin is disposed on the first end surface and the second end surface of the first insulating base;
a second pin, wherein the second pin is disposed on the first end surface and the second end surface of the first insulating base;
at least one first light-emitting assembly, wherein the at least one first light-emitting assembly is located on the first end surface of the first insulating base, and the at least one first light-emitting assembly is electrically connected to the first pin and the second pin;
at least one second light-emitting assembly, wherein the at least one second light-emitting assembly is located on the second end surface of the first insulating base, and the at least one second light-emitting assembly is electrically connected to the first pin and the second pin;
a first encapsulant, wherein the first encapsulant is disposed on the exterior of the at least one first light-emitting assembly and forms a first boss structure with the first insulating base, two sides of the first boss structure being configured to receive an external first wire and an external second wire, and the first wire and the second wire are electrically connected to the first pin and the second pin respectively;
a second encapsulant, wherein the second encapsulant is disposed on the exterior of the at least one second light-emitting assembly and forms a second boss structure with the first insulating base; and
a second insulating base and a third insulating base, wherein the second insulating base and the third insulating base are disposed on two sides of the second boss structure;
wherein the first wire and the second wire block light from a side surface of the at least one first light-emitting assembly, and the second insulating base and the third insulating base block light from a side surface of the at least one second light-emitting assembly.

According to a second aspect of the present disclosure, the present disclosure further provides an LED light strip, including:
a first wire and a second wire;
a plurality of LED beads as provided in any embodiment of the present disclosure, wherein the plurality of LED beads are electrically connected to the first wire and the second wire.

According to a third aspect of the present disclosure, the present disclosure further provides a cable, including:
an LED light strip as provided in any embodiment of the present disclosure.

The technical solutions provided by the embodiments of the present disclosure may include the following beneficial effects: the present disclosure provides an LED bead, an LED light strip and a cable, including a first insulating base, a first pin, a second pin, at least one first light-emitting assembly, at least one second light-emitting assembly, a first encapsulant, a second encapsulant, a second insulating base and a third insulating base. The first insulating base includes a first end surface and a second end surface disposed opposite to each other. The first pin is disposed on the first end surface and the second end surface of the first insulating base. The second pin is disposed on the first end surface and the second end surface of the first insulating base. The at least one first light-emitting assembly is located on the first end surface of the first insulating base, and the at least one first light-emitting assembly is electrically connected to the first pin and the second pin. The at least one second light-emitting assembly is located on the second end surface of the first insulating base, and the at least one second light-emitting assembly is electrically connected to the first pin and the second pin. The first encapsulant is disposed on the exterior of the at least one first light-emitting assembly and forms a first boss structure with the first insulating base, and two sides of the first boss structure are configured to receive an external first wire and an external second wire, which are electrically connected to the first pin and the second pin, respectively. The second encapsulant is disposed on the exterior of the at least one second light-emitting assembly and forms a second boss structure with the first insulating base. The second insulating base and the third insulating base are disposed on two sides of the second boss structure. The first wire and the second wire block light from a side surface of the at least one first light-emitting assembly, and the second insulating base and the third insulating base block light from a side surface of the at least one second light-emitting assembly, so that the light-emitting effect of the at least one first light-emitting assembly and the at least one second light-emitting assembly is the same.

In the LED bead provided by the present disclosure, the second insulating base and the third insulating base are disposed on two sides of the second boss structure, so that the LED bead can achieve uniform light emission on both sides. The LED bead provided by the present disclosure can be used in products such as high-density, small-pitch LED light strips and cables, so as to improve the color effect and display effect of the LED bead, enrich the light-emitting effect of the LED bead, achieve identical effects such as intensity, color and angle of the LED bead on upper and lower end surfaces, and realize flowing or running light effects based on a plurality of such LED beads.

It can be understood that both the foregoing general description and the following detailed description are exemplary and explanatory only and are not restrictive of the present disclosure.

### BRIEF DESCRIPTION OF THE DRAWINGS

To more clearly expound the technical solutions of embodiments of the present disclosure, a brief description will be provided below for the drawings that are necessary for illustrating the embodiments. Obviously, the drawings described below are provided for some of the embodiments of the present disclosure, and based on such drawings, those having ordinary skill in the art may obtain other drawings without creative effort.

FIG. 1 is a first structural schematic diagram showing an LED light strip according to an embodiment of the present disclosure;

FIG. 2 is a second structural schematic diagram showing an LED light strip according to an embodiment of the present disclosure;

FIG. 3 is a first structural schematic diagram showing an LED bead according to an embodiment of the present disclosure;

FIG. 4 is a second structural schematic diagram showing an LED bead according to an embodiment of the present disclosure;

FIG. 5 is a first exploded schematic diagram showing an LED bead according to an embodiment of the present disclosure;

FIG. 6 is a second exploded schematic diagram showing an LED bead according to an embodiment of the present disclosure;

FIG. 7 is a structural schematic diagram showing a first light-emitting assembly according to an embodiment of the present disclosure;

FIG. 8 is a structural schematic diagram showing a second light-emitting assembly according to an embodiment of the present disclosure;

FIG. 9 is a third structural schematic diagram showing an LED bead according to an embodiment of the present disclosure;

FIG. 10 is a first partial exploded schematic diagram showing an LED bead according to an embodiment of the present disclosure;

FIG. 11 is a second partial exploded schematic diagram showing an LED bead according to an embodiment of the present disclosure;

FIG. 12 is a fourth structural schematic diagram showing an LED bead according to an embodiment of the present disclosure;

FIG. 13 is a fifth structural schematic diagram showing an LED bead according to an embodiment of the present disclosure.

### LIST OF REFERENCE SIGNS

100, LED light strip; 10, LED bead; 11, first insulating base; 111, first end surface; 112, second end surface; 113, through hole; 12, first pin; 121, die bonding portion; 122, soldering portion; 13, second pin; 131, die bonding portion; 132, soldering portion; 14, first light-emitting assembly; 141, first light-emitting chipset; 1411, light-emitting chip; 142, driving chip; 15, second light-emitting assembly; 151, second light-emitting chipset; 1511, light-emitting chip; 16, first encapsulant; 161, first boss structure; 17, second encapsulant; 171, second boss structure; 18, second insulating base; 19, third insulating base; 10a, transition pin; 10b, conductive hole; 10c, address programming pin; 10c1, first address programming pin; 10c2, second address programming pin; 10d, solder resist material; 10e, address programming hole; 10f, fourth insulating base; 10g, fifth insulating base; 10h, sixth insulating base; 20, first wire; 30, second wire.

### DETAILED DESCRIPTION

The technical solutions in embodiments of the present disclosure will be clearly and completely described below with reference to the drawings in the embodiments of the present disclosure, and it is obvious that the described embodiments are a part of the embodiments of the present disclosure, but not all of the embodiments. Based on the embodiments of the present disclosure, all other embodiments obtained by those having ordinary skill in the art without any inventive work belong to the scope of the present disclosure.

It should also be understood that the terminology used in the description of the present disclosure is for the purpose of describing particular embodiments. In the description of the present disclosure, it should be understood that the terms “center”, “longitudinal”, “lateral”, “length”, “width”, “thickness”, “upper”, “lower”, “front”, “back”, “left”, “right”, “vertical”, “horizontal”, “top”, “bottom”, “inner”, “outer”, “center”, “clockwise”, “counterclockwise”, and the like refer to orientations or positional relationships based on orientations or positional relationships shown in the accompanying drawings, and are intended only to facilitate the description of the present application and to simplify the description, rather than indicating or implying that the device or element must have specific orientations or be constructed and operated in specific orientations. Therefore, the terms should not be understood as limitations on the present disclosure. Furthermore, the terms “first” and “second” are used only for descriptive purposes and should not be understood as indicating or implying relative importance or implying the number of the technical features indicated. Thus, features defined with “first” or “second” may explicitly or implicitly include one or more of the described features. In the description of the present disclosure, the terms “a plurality of” and “more than one” mean two or more, unless otherwise expressly and specifically limited.

Some embodiments of the present disclosure will be described in detail below with reference to the drawings. In the case of no conflict, the following embodiments and features in the embodiments may be combined with each other.

With the rapid development of the electronics industry, electronic products have gained widespread popularity in people's daily lives. Data cables for data transmission or charging of electronic products have become an indispensable part of our lives.

Existing data cables emit light via LED light strings disposed on USB connectors and charging plugs at both ends of the cable structure, and light is guided outward by forming notches on the surface of an optical fiber, so that the entire cable emits light. However, excessive notches on the surface of the optical fiber result in an excessive number of light spots exhibited by the cable. Meanwhile, since only a single type of light source essentially operates in a light string, the light-emitting pattern of the entire cable is monotonous.

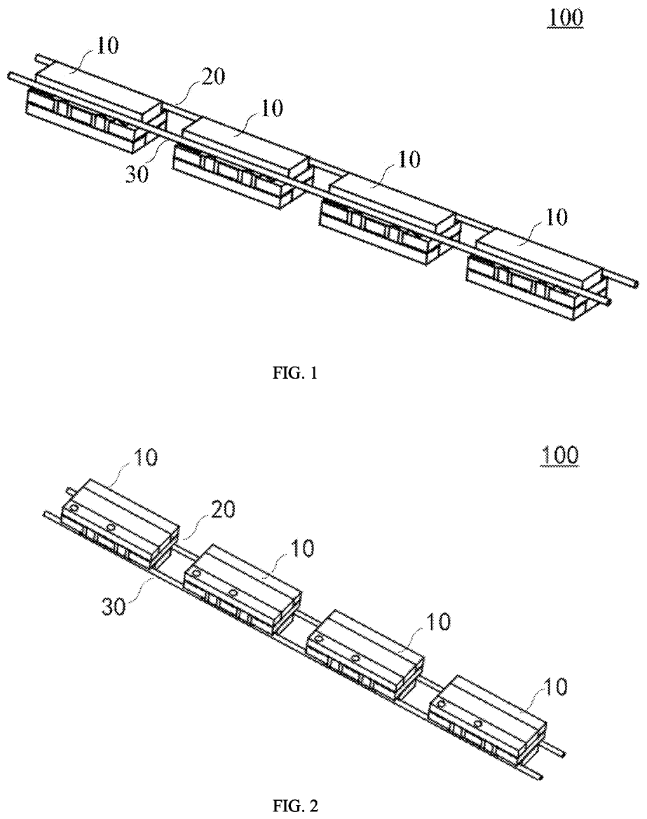

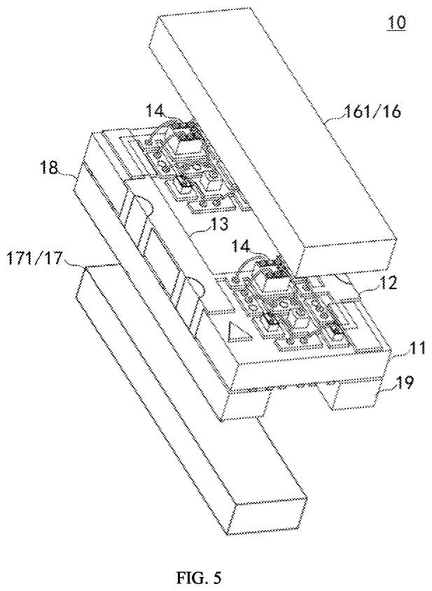

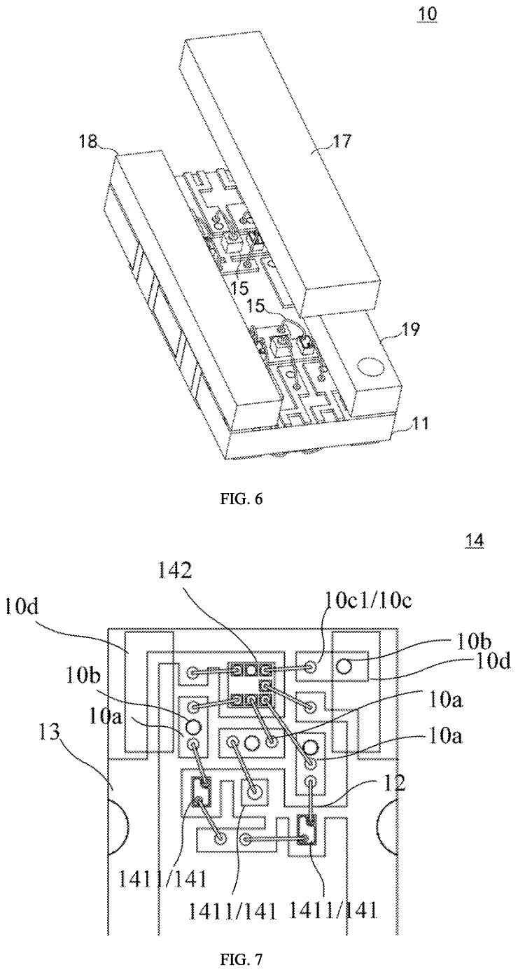

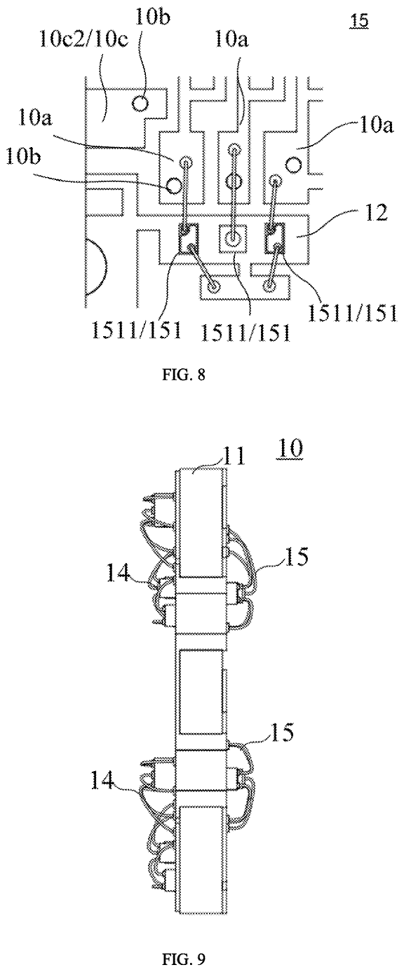

To solve the above problems, referring to FIGS. 1 to 11, the present disclosure provides an LED bead 10, including a first insulating base 11, a first pin 12, a second pin 13, at least one first light-emitting assembly 14, at least one second light-emitting assembly 15, a first encapsulant 16, a second encapsulant 17, a second insulating base 18 and a third insulating base 19. The first insulating base 11 includes a first end surface 111 and a second end surface 112 disposed opposite to each other. The first pin 12 is disposed on the first end surface 111 and the second end surface 112 of the first insulating base 11. The second pin 13 is disposed on the first end surface 111 and the second end surface 112 of the first insulating base 11. The at least one first light-emitting assembly 14 is located on the first end surface 111 of the first insulating base 11, and the at least one first light-emitting assembly 14 is electrically connected to the first pin 12 and the second pin 13. The at least one second light-emitting assembly 15 is located on the second end surface 112 of the first insulating base 11, and the at least one second light-emitting assembly 15 is electrically connected to the first pin 12 and the second pin 13. The first encapsulant 16 is disposed on the exterior of the at least one first light-emitting assembly 14 and forms a first boss structure 161 with the first insulating base 11, and two sides of the first boss structure 161 are configured to receive an external first wire 20 and an external second wire 30, which are electrically connected to the first pin 12 and the second pin 13, respectively. The second encapsulant 17 is disposed on the exterior of the at least one second light-emitting assembly 15 and forms a second boss structure 171 with the first insulating base 11. The second insulating base 18 and the third insulating base 19 are disposed on two sides of the second boss structure 171. The first wire 20 and the second wire 30 block light from a side surface of the at least one first light-emitting assembly 14, and the second insulating base 18 and the third insulating base 19 block light from a side surface of the at least one second light-emitting assembly 15, so that the light-emitting effect of the at least one first light-emitting assembly 14 and the at least one second light-emitting assembly 15 is the same. The light-emitting effect includes factors such as color, light intensity and angle.

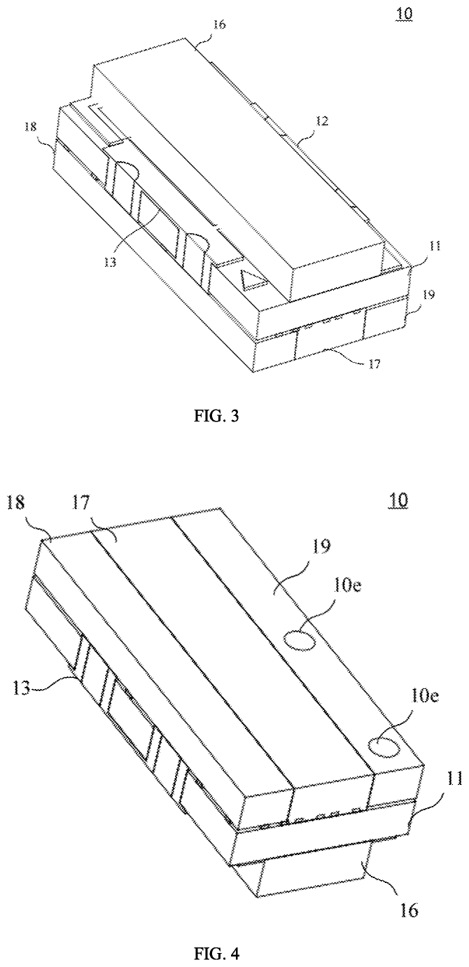

Specifically, as shown in FIGS. 3 to 6, the LED bead 10 uses the first insulating base 11 as a base material, and the at least one first light-emitting assembly 14 is disposed on the first end surface 111 of the first insulating base 11, while the at least one second light-emitting assembly 15 is disposed on the second end surface 112 of the first insulating base 11 opposite to the first end surface 111. Since the first encapsulant 16 is disposed on the exterior of the at least one first light-emitting assembly 14 of the LED bead 10, the first boss structure 161 is formed on the exterior of the first encapsulant 16. When the LED bead 10 is driven, the first wire 20 and the second wire 30 need to be electrically connected to the first pin 12 and the second pin 13 on two sides of the first boss structure 161, respectively, so as to drive the at least one first light-emitting assembly 14 and the at least one second light-emitting assembly 15 to emit light. As shown in FIGS. 1 and 2, when the first wire 20 and the second wire 30 are electrically connected to the LED bead 10, the first wire 20 and the second wire 30 block light from two sides of the first boss structure 161 of the LED bead 10. When the LED bead 10 is lit at this time, light emitted by the at least one first light-emitting assembly 14 and the at least one second light-emitting assembly 15 will be uneven in the upper and lower directions. Meanwhile, the light-emitting effect of the LED bead 10 includes factors such as color, light intensity and angle, making the LED bead 10 unsatisfactory in achieving flowing and running light effects.

To achieve consistent light-emitting effects between the at least one first light-emitting assembly 14 and the at least one second light-emitting assembly 15, the LED bead 10 of the present disclosure is provided with the second insulating base 18 and the third insulating base 19 on two sides of the second boss structure 171 outside the at least one second light-emitting assembly 15, so that the second insulating base 18 and the third insulating base 19 can also block light from two sides of the at least one second light-emitting assembly 15 of the LED bead 10. Furthermore, when the at least one first light-emitting assembly 14 and the at least one second light-emitting assembly 15 are driven to emit light simultaneously, the LED bead 10 can emit consistent light from both ends at the same angle, enriching the light-emitting effect of the LED bead 10.

In some embodiments, the height of the first wire 20 and the second wire 30 relative to two sides of the first boss structure 161 is defined as a first height. The height of the second insulating base 18 and the third insulating base 19 relative to two sides of the second boss structure 171 is defined as a second height. A difference between the second height and the first height is less than a predetermined threshold.

The first wire 20 and the second wire 30 are selected according to the actual application of the LED bead 10, and embodiments of the present disclosure do not limit specification parameters of the first wire 20 and the second wire 30. Meanwhile, in embodiments of the present disclosure, based on the height of the first wire 20 and the second wire 30 relative to the two sides of the first boss structure 161, the first wire 20 and the second wire 30 form light-blocking surfaces with the first height on the two sides of the first boss structure 161, such that light emitted by the at least one first light-emitting assembly 14 through side surfaces of the first boss structure 161 is blocked. Furthermore, by setting the height of the second insulating base 18 and the third insulating base 19 relative to two sides of the second boss structure 171 to a second height substantially equal to the first height, and by making the difference between the second height and the first height less than the predetermined threshold, the second insulating base 18 and the third insulating base 19 form light-blocking surfaces of the second height on two sides of the second boss structure 171. Thus, the degree of light blocking on two sides of the at least one second light-emitting assembly 15 approximates that of the at least one first light-emitting assembly 14, achieving highly consistent upper and lower light-emitting effects of the LED bead 10.

It should be noted that, to improve the manufacturing speed and reduce the cost of the LED bead, the LED bead can be manufactured by making the first height and the second height substantially the same. The difference between the first height and the second height is set according to precision requirements of an actual product. For example, the first height and the second height are considered substantially equal when the difference between the first height and the second height is within the predetermined threshold, such as ±5 mm. Embodiments of the present disclosure do not limit the predetermined threshold between the first height and the second height.

In some embodiments, as shown in FIGS. 7 and 8, each first light-emitting assembly 14 includes a first light-emitting chipset 141 and a driving chip 142, and the first light-emitting chipset 141 is electrically connected to the driving chip 142. Each second light-emitting assembly 15 includes a second light-emitting chipset 151, and the second light-emitting chipset 151 is electrically connected to the driving chip 142. The driving chip 142 is configured to control light emission of the first light-emitting chipset 141 and the second light-emitting chipset 151.

To simplify the structure of the LED bead 10, in embodiments of the present disclosure, the driving chip 142 of the first light-emitting assembly 14 is electrically connected to both the first light-emitting chipset 141 and the second light-emitting chipset 151, so that the driving chip 142 can control light emission of the first light-emitting chipset 141 and the second light-emitting chipset 151 respectively. This simplifies the control logic of the LED bead 10 and also reduces the cost of the LED bead 10.

It should be noted that the LED bead provided in embodiments of the present disclosure may also be provided with a corresponding driving chip 142 in the second light-emitting assembly 15, so as to independently control the first light-emitting chipset 141 and the second light-emitting chipset 151.

In some embodiments, referring to FIGS. 7 to 11, the driving chip 142, a light-emitting chip 1411 of the first light-emitting chipset 141, and a light-emitting chip 1511 of the second light-emitting chipset 151 are electrically connected to the first pin 12, and the driving chip 142 is electrically connected to the second pin 13. The first pin 12 includes a die bonding portion 121 and a soldering portion 122, and the second pin 13 includes a die bonding portion 131 and a soldering portion 132. The die bonding portion 121 of the first pin 12 is disposed on the first end surface 111 and the second end surface 112 of the first insulating base 11, and the die bonding portion 131 of the second pin 13 is disposed on the second end surface 112 of the first insulating base 11. The soldering portion 122 of the first pin 12 is disposed on the first end surface 111 and the second end surface 112 of the first insulating base 11, and the soldering portion 132 of the second pin 13 is disposed on the first end surface 111 and the second end surface 112 of the first insulating base 11. The soldering portions 122 and 132 on the first end surface 111 and the second end surface 112 are respectively connected through via holes to enhance the soldering strength of the LED bead 10, such that the via structure can accommodate a portion of soldering material. The die bonding portion 121 of the first pin 12 and the die bonding portion 131 of the second pin 13 are both located inside the first encapsulant 16 and the second encapsulant 17, and the soldering portion 122 of the first pin 12 and the soldering portion 132 of the second pin 13 are located outside the first encapsulant 16 and the second encapsulant 17.

It should be noted that, in some embodiments, the light-emitting chip 1411 of the first light-emitting chipset 141 is disposed on the die bonding portion 121 of the first pin 12 located on the first end surface 111. In some embodiments, the light-emitting chip 1411 of the first light-emitting chipset 141 is disposed on the die bonding portion 131 of the second pin 13 located on the first end surface 111. Embodiments of the present disclosure do not limit the position of the light-emitting chip 1411 of the first light-emitting chipset 141.

It should be noted that, in some embodiments, the driving chip 142 is disposed on the die bonding portion 121 of the first pin 12 located on the first end surface 111. In some embodiments, the driving chip 142 is disposed on the die bonding portion of the second pin located on the first end surface. Embodiments of the present disclosure do not limit the position of the driving chip 142 on the first end surface.

It should be noted that, in some embodiments, the light-emitting chip 1511 of the second light-emitting chipset 151 is disposed on the die bonding portion 121 of the first pin 12 located on the second end surface 112.

It should be noted that, in some embodiments, the second pin 13 is also formed with a die bonding portion 131 on the second end surface 112. In this case, the driving chip 142 can be disposed on the second end surface 112, and the light-emitting chip 1511 of the second light-emitting chipset 151 can also be disposed on the die bonding portion 131 of the second pin 13 located on the second end surface 112.

It should be noted that, in some embodiments, referring to FIGS. 7, 8 and 10, the LED bead 10 further includes at least one transition pin 10a. The at least one transition pin 10a is disposed on the first end surface 111 of the first insulating base 11 and the second end surface 112 of the first insulating base 11. The light-emitting chip 1511 of the second light-emitting chipset 151 is electrically connected to a transition pin 10a on the second end surface 112, and the light-emitting chip 1411 of the first light-emitting chipset 141 and the driving chip 142 are electrically connected to a transition pin 10a on the first end surface 111.

In some embodiments, the LED bead 10 further includes at least one conductive hole 10b. Each conductive hole 10b electrically connects the transition pin 10a on the first end surface 111 and the transition pin 10a on the second end surface 112. The driving chip 142 is electrically connected to the second light-emitting chipset 151 through the conductive hole 10b.

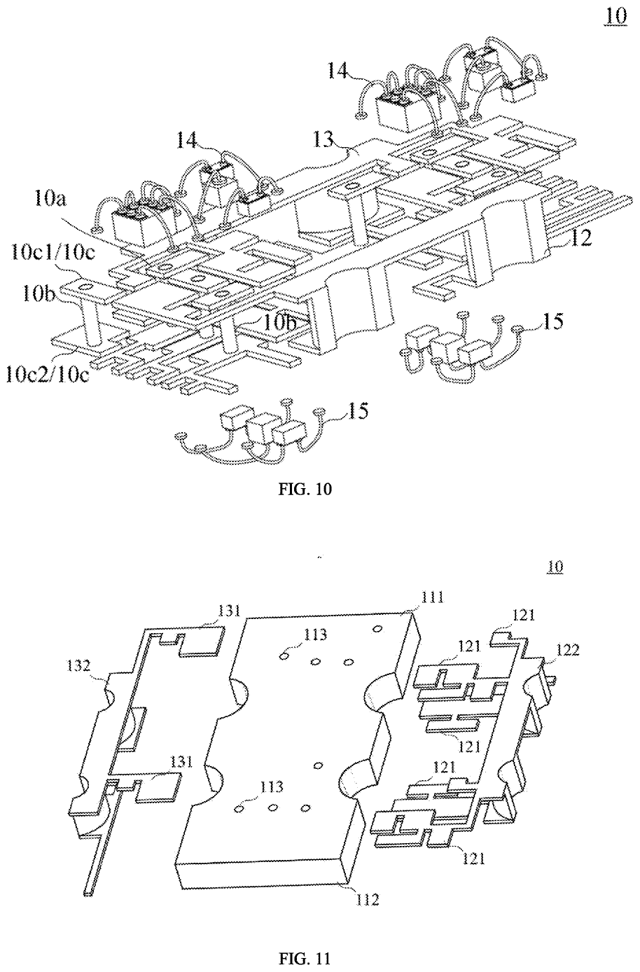

As shown in FIGS. 10 to 11, to simplify the structure of the LED bead 10, in embodiments of the present disclosure, a plurality of through holes 113 are formed in the first insulating base 11, so that the conductive hole 10b can electrically connect the transition pin 10a on the first end surface 111 and the second end surface 112 through the through holes 113. Thus, the driving chip 142 can be electrically connected to the first light-emitting chipset 141 and the second light-emitting chipset 151 respectively, enabling control of the first light-emitting chipset 141 and the second light-emitting chipset 151. Meanwhile, the conductive hole 10b may be a copper hole or any other conductive structure made of a conductive material, and embodiments of the present disclosure do not limit the type of the conductive hole 10b.

It should be noted that, in some embodiments, each of the first light-emitting chipset 141 and the second light-emitting chipset 151 includes a red chip, a green chip and a blue chip. The red chip, the green chip and the blue chip of the first light-emitting chipset 141 are equally spaced on the die bonding portion of the first end surface 111, and the red chip, the green chip and the blue chip of the second light-emitting chipset 151 are equally spaced on the die bonding portion of the second end surface 112. The LED bead 10 includes three groups of transition pin pairs, each group including two transition pins 10a disposed oppositely on the first end surface 111 and the second end surface 112 of the first insulating base 11. The three groups of transition pin pairs are respectively defined as a first transition pin pair, a second transition pin pair and a third transition pin pair, respectively. The conductive hole 10b includes a first conductive hole, a second conductive hole and a third conductive hole. The first conductive hole is electrically connected to two transition pins 10a of the first transition pin pair, the second conductive hole is electrically connected to two transition pins 10a of the second transition pin pair, and the third conductive hole is electrically connected to two transition pins 10a of the third transition pin pair.

Meanwhile, the red chip of the first light-emitting chipset 141 and the driving chip 142 are electrically connected to the transition pin 10a of the first transition pin pair located on the first end surface 111. The red chip of the second light-emitting chipset 151 is electrically connected to the transition pin 10a of the first transition pin pair located on the second end surface 112. The driving chip 142 can control light emission of the red chip of the first light-emitting chipset 141 and the red chip of the second light-emitting chipset 151. The green chip of the first light-emitting chipset 141 and the driving chip 142 are electrically connected to the transition pin 10a of the second transition pin pair located on the first end surface 111. The green chip of the second light-emitting chipset 151 is electrically connected to the transition pin 10a of the second transition pin pair located on the second end surface 112. The driving chip 142 can control light emission of the green chip of the first light-emitting chipset 141 and the green chip of the second light-emitting chipset 151. The blue chip of the first light-emitting chipset 141 and the driving chip 142 are electrically connected to the transition pin 10a of the third transition pin pair located on the first end surface, and the blue chip of the second light-emitting chipset 151 is electrically connected to the transition pin 10a of the third transition pin pair located on the second end surface. The driving chip 142 can control light emission of the blue chip of the first light-emitting chipset 141 and the blue chip of the second light-emitting chipset 151.

Accordingly, the above structure enables the driving chip 142 to simultaneously control light emission of chips of the same color. In addition, the first light-emitting chipset 141 and the second light-emitting chipset 151 are not limited to red, green and blue, but may include any combination of yellow, white, and other colored light-emitting chips. Embodiments of the present disclosure do not limit the type of light-emitting chips of the first light-emitting chipset 141 and the second light-emitting chipset 151.

It should be noted that, in some embodiments, the transition pin 10a is disposed between the die bonding portion where the first light-emitting chipset 141 is disposed and the die bonding portion where the driving chip 142 is disposed. The arrangement of the transition pin 10a can also reduce the length of a bonding wire connecting the driving chip 142 and the first light-emitting chipset 141, thus preventing breakage of the bonding wire.

In some embodiments, the number of the first light-emitting chipsets 141 is equal to the number of the second light-emitting chipsets 151. Thus, the light emission of the first end surface 111 and the second end surface 112 of the LED bead 10 can be completely consistent.

In some embodiments, the number of the driving chips 142 is equal to the number of the first light-emitting chipsets 141. Thus, the light emission of the first end surface 111 and the second end surface 112 of the LED bead 10 can be completely consistent.

In some embodiments, the type of the light-emitting chip 1411 of the first light-emitting chipset 141 is the same as the type of the light-emitting chip 1511 of the second light-emitting chipset 151. Thus, the light emission of the first end surface 111 and the second end surface 112 of the LED bead 10 can be completely consistent.

In some embodiments, the first boss structure 161 and the second boss structure 171 are the same size, ensuring that light emitted by the first light-emitting assembly 14 and the second light-emitting assembly 15 through the first boss structure 161 and the second boss structure 171 is uniform.

In some embodiments, referring to FIG. 4, FIGS. 7 to 8 and FIG. 10, the LED bead 10 further includes an address programming pin 10c electrically connected to the driving chip 142. Address information is written to the driving chip 142 via the address programming pin 10c. With the above structure, a corresponding address can be written to the driving chip 142 of the LED bead 10 quickly and accurately, enabling accurate control of each LED bead 10 when the LED beads 10 are configured to form an LED light strip 100.

It should be noted that, in some embodiments, referring to FIG. 4 and FIGS. 7 to 8, the address programming pin 10c includes a first address programming pin 10c1 and a second address programming pin 10c2. The first address programming pin 10c1 is disposed on the first end surface 111 of the first insulating base 11, and the second address programming pin 10c2 is disposed on the second end surface 112 of the first insulating base 11. The driving chip 142 is electrically connected to the first address programming pin 10c1. The LED bead 10 further includes a conductive hole 10b electrically connecting the first address programming pin 10c1 and the second address programming pin 10c2. The driving chip 142 is electrically connected to the second address programming pin 10c2 via the conductive hole 10b. The second insulating base 18 or the third insulating base 19 includes an address programming hole 10e disposed relative to the second address programming pin 10c2. Address information is written to the driving chip 142 via the address programming hole 10e and the second address programming pin 10c2.

Address information can be accurately written to the driving chip 142 by means such as probe programming via the address programming hole 10e, thereby achieving precise management of the LED bead 10.

In some embodiments, the LED bead 10 includes a plurality of first light-emitting chipsets 141, a plurality of second light-emitting chipsets 151 and a plurality of first driving chips 142. A plurality of first light-emitting assemblies 14 are arranged at equal intervals on the first end surface 111 along a length direction of the first insulating base 11, and a plurality of second light-emitting assemblies 15 are arranged at equal intervals on the second end surface 112 along the length direction of the first insulating base 11.

Embodiments of the present disclosure do not limit the number of the first light-emitting chipsets 141, the second light-emitting chipsets 151 and the first driving chips 142, which are specifically set according to actual needs. Meanwhile, by arranging the first light-emitting assemblies 14 and the second light-emitting assemblies 15 at equal intervals along the length direction of the first insulating base 11, consistent light-emitting effects of the first light-emitting assemblies 14 and the second light-emitting assemblies 15 of the LED bead 10 can be ensured

In some embodiments, when the LED bead 10 includes two first light-emitting chipsets 141, two second light-emitting chipsets 151 and two first driving chips 142, the two first light-emitting assemblies 14 are disposed at two ends of the first end surface 111 along the length direction of the first insulating base 11, and the two second light-emitting assemblies 15 are disposed at two ends of the second end surface 112 along the length direction of the first insulating base 11.

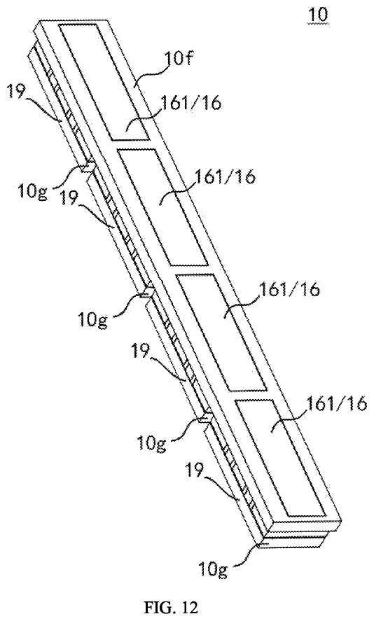

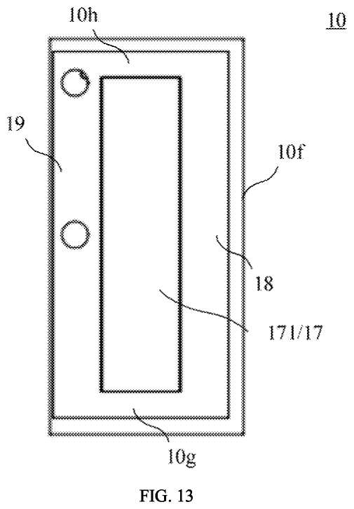

In some embodiments, referring to FIGS. 12 to 13, the LED bead 10 further includes a fourth insulating base 10f. The fourth insulating base 10f includes a bead receiving area, and the first boss structure 161 of the LED bead is disposed in the bead receiving area. The LED bead 10 further includes a fifth insulating base 10g and a sixth insulating base 10h, and the fifth insulating base 10g and the sixth insulating base 10h are disposed on the other two sides of the second boss structure 171. The first wire 20, the second wire 30 and the fourth insulating base 10f block light from the periphery of the at least one first light-emitting assembly 14, and the second insulating base 18, the third insulating base 19, the fifth insulating base 10g and the sixth insulating base 10h block light from the periphery of the at least one second light-emitting assembly 15, so that the first light-emitting assembly 14 and the second light-emitting assembly 15 emit light evenly.

In some embodiments, the fourth insulating base 10f may be a printed circuit board (PCB), and the first wire 20 and the second wire 30 are embedded on two sides of the PCB. When a groove is formed in the PCB for receiving the LED bead 10, the thickness of the PCB blocks the other two side surfaces of the first light-emitting assembly 14. Thus the fifth insulating base 10g and the sixth insulating base 10h are disposed to block the other two side surfaces of the second light-emitting assembly 15, so that the first light-emitting assembly 14 and the second light-emitting assembly 15 have the same light-emitting effect, i.e., the same light intensity, color and angle.

In some embodiments, the second insulating base 18, the third insulating base 19, the fifth insulating base 10g and the sixth insulating base 10h are integrally formed.

In some embodiments, the materials of the first insulating base 11, the second insulating base 18, the third insulating base 19, the fourth insulating base 10f, the fifth insulating base 10g and the sixth insulating base 10h may be the same or different, such as ceramic, substrate, BT board or any other materials. The materials of the second insulating base 18, the third insulating base 19, the fourth insulating base 10f, the fifth insulating base 10g and the sixth insulating base 10h may also be any opaque colloid or light-blocking glass plate. Embodiments of the present disclosure do not limit the materials of the first insulating base 11, the second insulating base 18, the third insulating base 19, the fourth insulating base 10f, the fifth insulating base 10g and the sixth insulating base 10h.

In some embodiments, the first pin 12 is a power supply pin, and the second pin 13 is a ground pin. Furthermore, the driving chip 142 controls the first light-emitting assembly 14 and the second light-emitting assembly 15 by implementing a power line carrier scheme via the first pin 12 and the second pin 13.

Referring to FIGS. 1 to 2, an embodiment of the present disclosure provides an LED light strip 100, including a first wire 20, a second wire 30 and a plurality of LED beads 10 provided in any embodiment of the present disclosure. The plurality of LED beads 10 are electrically connected to the first wire 20 and the second wire 30.

Specifically, with the LED light strip 100, a plurality of LED beads 10 can be driven to emit light simultaneously, and the LED beads 10 can emit light with the same angle, light intensity and color from two end surfaces, so that the LED light strip can achieve flowing, running light effects or other effects, enriching the light-emitting effects of the LED light strip and products designed based on the LED light strip.

In some embodiments, the plurality of LED beads 10 are connected at intervals via the first wire 20 and the second wire 30, so that the colors of the LED light strip 100 are more uniform during operation.

It should be noted that the LED light strip is arranged with a plurality of LED beads at equal intervals, so as to achieve a high-density, small-pitch design of the LED light strip, improve the color effect and display effect of the LED light strip, and make the resolution of LED products more delicate. The LED light strip is used in applications including, but not limited to, display screens, data cables and the like.

An embodiment of the present disclosure provides a cable. The cable includes the LED light strip provided in any embodiment of the present disclosure, which can ensure consistent optical path brightness of each light-emitting area of the entire cable, so that the light-emitting pattern of the cable structure is richer and the light-emitting effect is better.

In some embodiments, the cable includes a light homogenizing tube, and the light homogenizing tube is disposed outside the LED light strip. A light-transmitting hole is formed on the exterior of the light homogenizing tube, so that light emitted by the LED light strip can pass through the light-transmitting hole. The light homogenizing tube can cooperate with the LED light strip, so that the LED light strip has a good light-emitting effect, avoids glare, can achieve full-surface light emission, and improves the overall light-emitting effect of the cable.

In the description of the present disclosure, it should be noted that, unless otherwise clearly specified and limited, the terms “installed”, “connected”, “coupled” should be understood in a broad sense, for example, may be a fixed connection, or may be a detachable connection, or may be an integral connection. It can be a mechanical connection or an electric connection. It can be a direct connection, or an indirect connection through an intermediate medium, or it can be internal communication between two elements or an interaction relation between the two elements. For those having ordinary skill in the art, the specific meaning of the above terms in the present disclosure can be understood according to specific situations.

In the present disclosure, unless otherwise clearly specified and limited, a first feature being “on” or “under” a second feature may include a direct contact between the first feature and the second feature, or may include an additional feature contact between the first feature and the second feature instead of the direct contact. Moreover, the first feature being “above”, “on top of” the second feature includes the first feature being directly above and diagonally above the second feature, or only indicating that a horizontal height of the first feature is higher than a horizontal height of the second feature. The first feature being “under”, “below” and “on a lower side” of the second feature includes the first feature directly under and diagonally under the second feature, or only indicates that a horizontal height of the first feature is less than a horizontal height of the second feature.

The above disclosure provides different embodiments or examples for implementing different structures of the present disclosure. In order to simplify disclosure of the present disclosure, components and arrangements of specific examples are described above. Of course, they are only examples and are not intended to limit the present disclosure. In addition, the present disclosure may repeat reference numbers and/or reference letters in different examples, such repetitions being for simplicity and clarity, which do not indicate the relationship between the various embodiments and/or arrangements being discussed. In addition, the present disclosure provides examples of various specific processes and materials, but those having ordinary skill in the art can recognize the application of other processes and/or use of other materials.

In the description of the specification, terms “one embodiment”, “some embodiments”, “exemplary embodiments”, “for example”, “specific example”, or “such as” mean that specific method steps, features, structures, materials or characteristics described in combination with one embodiment or one example are included in at least one embodiment or one example of the present application. In the specification, the illustrative expressions of the above terms do not necessarily refer to the same embodiment or example. Moreover, the specific method steps, features, structures, materials, or features described may be combined in a suitable manner in any one or more embodiments or examples.

What is claimed is:

1. An LED bead, comprising:
a first insulating base, wherein the first insulating base comprises a first end surface and a second end surface disposed opposite to each other;
a first pin, wherein the first pin is disposed on the first end surface and the second end surface of the first insulating base;
a second pin, wherein the second pin is disposed on the first end surface and the second end surface of the first insulating base;
at least one first light-emitting assembly, wherein the at least one first light-emitting assembly is located on the first end surface of the first insulating base, and the at least one first light-emitting assembly is electrically connected to the first pin and the second pin;
at least one second light-emitting assembly, wherein the at least one second light-emitting assembly is located on the second end surface of the first insulating base, and the at least one second light-emitting assembly is electrically connected to the first pin and the second pin;
a first encapsulant, wherein the first encapsulant is disposed on the exterior of the at least one first light-emitting assembly and forms a first boss structure with the first insulating base, two sides of the first boss structure being configured to receive an external first wire and an external second wire, and the first wire and the second wire are electrically connected to the first pin and the second pin respectively;
a second encapsulant, wherein the second encapsulant is disposed on the exterior of the at least one second light-emitting assembly and forms a second boss structure with the first insulating base; and
a second insulating base and a third insulating base, wherein the second insulating base and the third insulating base are disposed on two sides of the second boss structure;
wherein the first wire and the second wire block light from a side surface of the at least one first light-emitting assembly, and the second insulating base and the third insulating base block light from a side surface of the at least one second light-emitting assembly.

2. The LED bead according to claim 1, wherein
the height of the first wire and the second wire relative to two sides of the first boss structure is defined as a first height;
the height of the second insulating base and the third insulating base relative to two sides of the second boss structure is defined as a second height;
wherein a difference between the second height and the first height is less than a predetermined threshold.

3. The LED bead according to claim 1, wherein
each first light-emitting assembly comprises a first light-emitting chipset and a driving chip, and the first light-emitting chipset is electrically connected to the driving chip;
each second light-emitting assembly comprises a second light-emitting chipset, and the second light-emitting chipset is electrically connected to the driving chip;
wherein the driving chip is configured to control light emission of the first light-emitting chipset and the second light-emitting chipset.

4. The LED bead according to claim 3, wherein the driving chip, light-emitting chips of the first light-emitting chipset and the second light-emitting chipset are electrically connected to the first pin, and the driving chip is electrically connected to the second pin;
each of the first pin and the second pin comprises a die bonding portion and a soldering portion; the die bonding portion of the first pin is disposed on the first end surface and the second end surface of the first insulating base, and the die bonding portion of the second pin is disposed on the second end surface of the first insulating base; the soldering portion of the first pin is disposed on the first end surface and the second end surface of the first insulating base, and the soldering portion of the second pin is disposed on the first end surface and the second end surface of the first insulating base; the soldering portions on the first end surface and the second end surface are connected through via holes; the die bonding portion of the first pin and the die bonding portion of the second pin are both located inside the first encapsulant and the second encapsulant, and the soldering portion of the first pin and the soldering portion of the second pin are located outside the first encapsulant and the second encapsulant;
wherein a light-emitting chip of the first light-emitting chipset is disposed on the die bonding portion of the first pin located on the first end surface, or disposed on the die bonding portion of the second pin located on the first end surface;
the driving chip is disposed on the die bonding portion of the first pin located on the first end surface, or disposed on the die bonding portion of the second pin located on the first end surface;
a light-emitting chip of the second light-emitting chipset is disposed on the die bonding portion of the first pin located on the second end surface.

5. The LED bead according to claim 4, wherein the LED bead further comprises:
at least one transition pin, wherein the at least one transition pin is disposed on the first end surface and the second end surface of the first insulating base; a light-emitting chip of the second light-emitting chipset is electrically connected to a transition pin on the second end surface, and light-emitting chip of the first light-emitting chipset and the driving chip are electrically connected to a transition pin on the first end surface;
at least one conductive hole, wherein each conductive hole electrically connects the transition pin on the first end surface and the transition pin on the second end surface, and the driving chip is electrically connected to the second light-emitting chipset through the conductive hole.

6. The LED bead according to claim 5, wherein
each of the first light-emitting chipset and the second light-emitting chipset comprises a red chip, a green chip and a blue chip; the red chip, the green chip and the blue chip of the first light-emitting chipset are equally spaced on the die bonding portion on the first end surface, and the red chip, the green chip and the blue chip of the second light-emitting chipset are equally spaced on the die bonding portion on the second end surface;
the LED bead comprises three groups of transition pin pairs, each group comprising two transition pins disposed oppositely on the first end surface and the second end surface of the first insulating base; the three transition pin pairs are respectively defined as a first transition pin pair, a second transition pin pair and a third transition pin pair,
the conductive holes comprise a first conductive hole, a second conductive hole and a third conductive hole; the first conductive hole is electrically connected to two transition pins of the first transition pin pair, the second conductive hole is electrically connected to two transition pins of the second transition pin pair, and the third conductive hole is electrically connected to two transition pins of the third transition pin pair;
the red chip of the first light-emitting chipset and the driving chip are electrically connected to the transition pin of the first transition pin pair located on the first end surface, and the red chip of the second light-emitting chipset is electrically connected to the transition pin of the first transition pin pair located on the second end surface; the driving chip is capable of controlling light emission of the red chips of the first light-emitting chipset and the second light-emitting chipset;
the green chip of the first light-emitting chipset and the driving chip are electrically connected to the transition pin of the second transition pin pair located on the first end surface, and the green chip of the second light-emitting chipset is electrically connected to the transition pin of the second transition pin pair located on the second end surface; the driving chip is capable of controlling light emission of the green chips of the first light-emitting chipset and the second light-emitting chipset;
the blue chip of the first light-emitting chipset and the driving chip are electrically connected to the transition pin of the third transition pin pair located on the first end surface, and the blue chip of the second light-emitting chipset is electrically connected to the transition pin of the third transition pin pair located on the second end surface; the driving chip is capable of controlling light emission of the blue chips of the first light-emitting chipset and the second light-emitting chipset.

7. The LED bead according to claim 5, wherein each transition pin is disposed between a die bonding portion where the first light-emitting chipset is disposed and a die bonding portion where the driving chip is disposed.

8. The LED bead according to claim 4, wherein the number of the first light-emitting chipsets is equal to the number of the second light-emitting chipsets.

9. The LED bead according to claim 4, wherein the number of the driving chips is equal to the number of the first light-emitting chipsets.

10. The LED bead according to claim 4, wherein the type of a light-emitting chip of the first light-emitting chipset is the same as the type of a light-emitting chip of the second light-emitting chipset.

11. The LED bead according to claim 4, wherein the LED bead further comprises:
an address programming pin, wherein the address programming pin is electrically connected to the driving chip, and address information is written to the driving chip via the address programming pin.

12. The LED bead according to claim 11, wherein the address programming pin comprises a first address programming pin and a second address programming pin, the first address programming pin is disposed on the first end surface of the first insulating base, the second address programming pin is disposed on the second end surface of the first insulating base, and the driving chip is electrically connected to the first address programming pin; the LED bead further comprises:
a conductive hole, wherein the conductive hole electrically connects the first address programming pin and the second address programming pin, and the driving chip is electrically connected to the second address programming pin via the conductive hole;
the second insulating base or the third insulating base comprises:
an address programming hole, wherein the address programming hole is disposed relative to the second address programming pin, and address information is written to the driving chip via the address programming hole and the second address programming pin.

13. The LED bead according to claim 1, wherein
the LED bead comprises a plurality of first light-emitting chipsets, a plurality of second light-emitting chipsets and a plurality of first driving chips;
a plurality of first light-emitting assemblies are arranged at equal intervals on the first end surface along a length direction of the first insulating base;
a plurality of second light-emitting assemblies are arranged at equal intervals on the second end surface along the length direction of the first insulating base.

14. The LED bead according to claim 1, wherein the LED bead further comprises:
a fourth insulating base, wherein the fourth insulating base includes a bead receiving area, and the first boss structure of the LED bead is disposed in the bead receiving area;
wherein the first wire, the second wire and the fourth insulating base are configured to block light from a periphery of the at least one first light-emitting assembly.

15. The LED bead according to claim 1, wherein the LED bead further comprises:
a fifth insulating base and a sixth insulating base, wherein the fifth insulating base and the sixth insulating base are disposed on the other two sides of the second boss structure;
wherein the second insulating base, the third insulating base, the fifth insulating base and the sixth insulating base are configured to block light from the periphery of the at least one second light-emitting assembly.

16. The LED bead according to claim 15, wherein the second insulating base, the third insulating base, the fifth insulating base and the sixth insulating base are integrally formed.

17. The LED bead according to claim 1, wherein
the first pin is a power supply pin, and the second pin is a ground pin.

18. An LED light strip, comprising:
a first wire and a second wire; and
a plurality of LED beads, wherein the plurality of LED beads are electrically connected to the first wire and the second wire; each LED bead comprises:
a first insulating base, wherein the first insulating base comprises a first end surface and a second end surface disposed opposite to each other;
a first pin, wherein the first pin is disposed on the first end surface and the second end surface of the first insulating base;
a second pin, wherein the second pin is disposed on the first end surface and the second end surface of the first insulating base;
at least one first light-emitting assembly, wherein the at least one first light-emitting assembly is located on the first end surface of the first insulating base, and the at least one first light-emitting assembly is electrically connected to the first pin and the second pin;
at least one second light-emitting assembly, wherein the at least one second light-emitting assembly is located on the second end surface of the first insulating base, and the at least one second light-emitting assembly is electrically connected to the first pin and the second pin;
a first encapsulant, wherein the first encapsulant is disposed on the exterior of the at least one first light-emitting assembly and forms a first boss structure with the first insulating base, two sides of the first boss structure being configured to receive an external first wire and an external second wire, and the first wire and the second wire are electrically connected to the first pin and the second pin respectively;
a second encapsulant, wherein the second encapsulant is disposed on the exterior of the at least one second light-emitting assembly and forms a second boss structure with the first insulating base; and
a second insulating base and a third insulating base, wherein the second insulating base and the third insulating base are disposed on two sides of the second boss structure;
wherein the first wire and the second wire block light from a side surface of the at least one first light-emitting assembly, and the second insulating base and the third insulating base block light from a side surface of the at least one second light-emitting assembly.

19. A cable, comprising: an LED light strip, wherein the LED light strip comprises:
a first wire and a second wire; and
a plurality of LED beads, wherein the plurality of LED beads are electrically connected to the first wire and the second wire; each LED bead comprises:
a first insulating base, wherein the first insulating base comprises a first end surface and a second end surface disposed opposite to each other;
a first pin, wherein the first pin is disposed on the first end surface and the second end surface of the first insulating base;
a second pin, wherein the second pin is disposed on the first end surface and the second end surface of the first insulating base;
at least one first light-emitting assembly, wherein the at least one first light-emitting assembly is located on the first end surface of the first insulating base, and the at least one first light-emitting assembly is electrically connected to the first pin and the second pin;
at least one second light-emitting assembly, wherein the at least one second light-emitting assembly is located on the second end surface of the first insulating base, and the at least one second light-emitting assembly is electrically connected to the first pin and the second pin;
a first encapsulant, wherein the first encapsulant is disposed on the exterior of the at least one first light-emitting assembly and forms a first boss structure with the first insulating base. two sides of the first boss structure being configured to receive an external first wire and an external second wire, and the first wire and the second wire are electrically connected to the first pin and the second pin respectively;
a second encapsulant, wherein the second encapsulant is disposed on the exterior of the at least one second light-emitting assembly and forms a second boss structure with the first insulating base; and
a second insulating base and a third insulating base, wherein the second insulating base and the third insulating base are disposed on two sides of the second boss structure;
wherein the first wire and the second wire block light from a side surface of the at least one first light-emitting assembly, and the second insulating base and the third insulating base block light from a side surface of the at least one second light-emitting assembly.

20. The cable according to claim 19, wherein the cable further comprises:
a light homogenizing tube, wherein the light homogenizing tube is disposed outside the LED light strip.
